(19) United States
(12) Patent Application Publication
(10) Pub. No.: US 2013/0264910 A1
(43) Pub. Date: Oct. 10, 2013

(54) PIEZOELECTRIC DEVICE

(71) Applicant: NIHON DEMPA KOGYO CO., LTD., Tokyo (JP)

(72) Inventor: TAKEHIRO TAKAHASHI, SAITAMA (JP)

(73) Assignee: NIHON DEMPA KOGYO CO., LTD., TOKYO (JP)

(21) Appl. No.: 13/845,079

(22) Filed: Mar. 17, 2013

(30) Foreign Application Priority Data
Apr. 9, 2012 (JP) 2012-088165

(51) Int. Cl. H01L 41/053

(52) U.S. Cl. CPC H01L 41/053
USPC 310/348

(57) ABSTRACT

A surface mount piezoelectric device with a piezoelectric vibrating piece to be mounted on a surface of a printed circuit board includes a base substrate, a groove, and at least a pair of mounting terminals. The base substrate is formed of an insulating material. The base substrate includes a mounting surface to be mounted on the printed circuit board. The groove is formed on at least a part of a periphery of the mounting terminal. The groove has a bottom surface and a side surface. The side surface extends from the bottom surface to the mounting surface. The pair of mounting terminals are formed on the mounting surface and the side surface.

### CROSS REFERENCE TO RELATED APPLICATIONS

This application claims the priority benefit of Japan application serial no. 2012-088165, filed on Apr. 9, 2012. The entirety of the above-mentioned patent application is hereby incorporated by reference herein and made a part of this specification.

### TECHNICAL FIELD

This disclosure relates to a piezoelectric device to be mounted on a printed circuit board. Especially, this disclosure relates to a structure of a mounting terminal that is formed on a mounting surface of a base substrate of the piezoelectric device.

### DESCRIPTION OF THE RELATED ART

A surface mount piezoelectric device has been downsized. Accordingly, a distance between mounting terminals of the piezoelectric device has become narrow. When the piezoelectric device is soldered to a printed circuit board, solder that overflows between the mounting terminals connects respective terminals, thus resulting in a short circuit. On the other hand, if the amount of a paste solder reduced, an electrical conduction between the mounting terminal and a wiring pad of the printed circuit board may be insufficient.

To solve the above-described problems, Japanese Unexamined Patent Application Publication No. 2001-326445 (hereinafter referred to as Patent Literature 1) includes a depressed portion disposed between the mounting terminals. When the mounting terminals are solder-connected on the wiring pad of the printed circuit board, the depressed portion blocks the flow of melted solder flowing from one mounting terminal to another mounting terminal.

On the other hand, downsizing of the piezoelectric device reduces an area for the mounting terminal. This may cause a problem that the piezoelectric device is detached by bending stress applied to the printed circuit board or similar stress. The piezoelectric device disclosed in Patent Literature 1 cannot solve the problem of detachment of the piezoelectric device.

A need thus exists for a piezoelectric device which is not susceptible to the drawbacks mentioned above.

### SUMMARY

A surface mount piezoelectric device with a piezoelectric vibrating piece to be mounted on a surface of a printed circuit board includes a base substrate, a groove, and at least a pair of mounting terminals. The base substrate is formed of an insulating material. The base substrate includes a mounting surface to be mounted on the printed circuit board. The groove is formed on at least a part of a periphery of the mounting terminal. The groove has a bottom surface and a side surface. The side surface extends from the bottom surface to the mounting surface. The pair of mounting terminals are formed on the mounting surface and the side surface.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a piezoelectric device 100; FIG. 2A is a plan view of the surface at the −Y′-axis side of a base substrate 120;

FIG. 2B is a cross-sectional view of a printed circuit board 160 and the piezoelectric device 100;

FIG. 3A is a plan view of the surface at the −Y′-axis side of a base substrate 220;

FIG. 3B is a cross-sectional view taken along the line IIIB-IIIB of FIG. 3A; FIG. 4A is a perspective view of the surface at the −Y′-axis side of a base substrate 320;

FIG. 4B is a plan view of the surface at the −Y′-axis side of the base substrate 320;

FIG. 5A is a perspective view of the surface at the −Y′-axis side of a base substrate 420;

FIG. 5B is a plan view of the surface at the −Y′-axis side of the base substrate 420;

FIG. 6A is a perspective view of the surface at the −Y′-axis side of a base substrate 520;

FIG. 6B is a plan view of the surface at the −Y′-axis side of the base substrate 520;

FIG. 7A is a perspective view of the surface at the −Y′-axis side of a base substrate 620;

FIG. 7B is a plan view of the surface at the −Y′-axis side of the base substrate 620;

FIG. 8A is a perspective view of the surface at the −Y′-axis side of a base substrate 720; and

FIG. 8B is a plan view of the surface at the −Y′-axis side of the base substrate 720.

### DETAILED DESCRIPTION

The preferred embodiments of this disclosure will be described with reference to the attached drawings. It will be understood that the scope of the disclosure is not limited to the described embodiments, unless otherwise stated.

### Constitution of a Piezoelectric Device 100 According to a First Embodiment

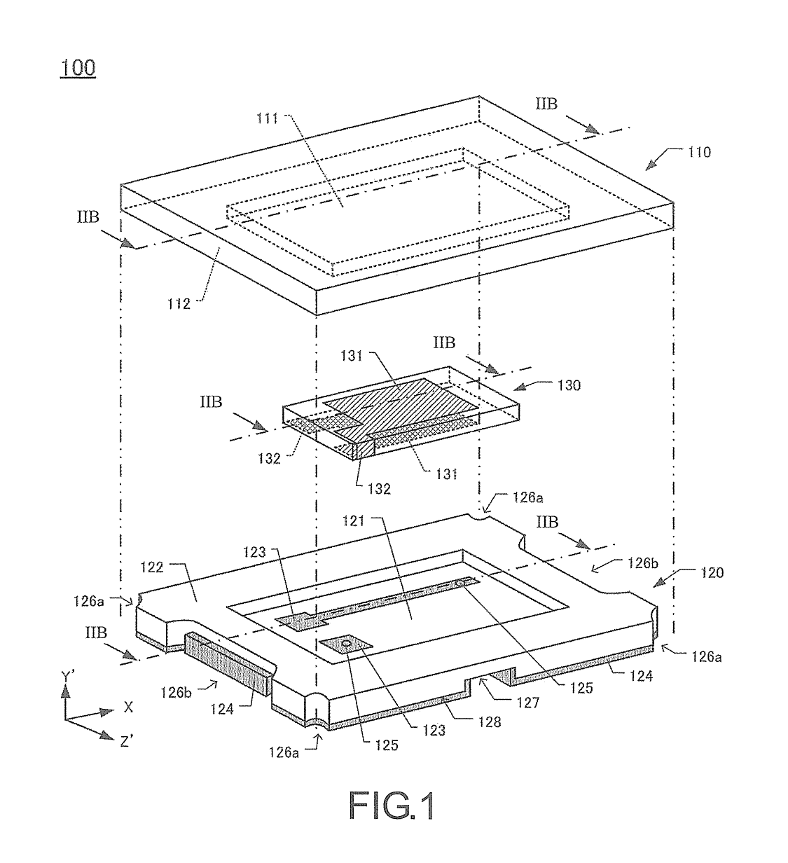

FIG. 1 is an exploded perspective view of the piezoelectric device 100. The piezoelectric device 100 includes a piezoelectric vibrating piece 130, a lid substrate 110, and a base substrate 120. An AT-cut quartz-crystal vibrating piece, for example, is employed for the piezoelectric vibrating piece 130. The AT-cut quartz-crystal vibrating piece has a principal surface (in the Y-Z plane) that is tilted by 35° 15′ about the Y-axis of crystallographic axes (XYZ) in the direction from the Z-axis to the Y-axis around the X-axis. In the following description, the new axes tilted with reference to the axis directions of the AT-cut quartz-crystal vibrating piece are denoted as the Y′-axis and the Z′-axis. This disclosure defines the long side direction of the piezoelectric device 100 as the X-axis direction, the height direction of the piezoelectric device 100 as the Y′-axis direction, and the direction perpendicular to the X and Y′-axis directions as the Z′-axis direction.

In the piezoelectric device 100, the piezoelectric vibrating piece 130, which vibrates at a predetermined vibration frequency, is placed on the surface at the +Y′-axis side of the base substrate 120. Further, the lid substrate 110 is bonded to the base substrate 120 to seal the piezoelectric vibrating piece 130, thus the piezoelectric device 100 is formed.

The piezoelectric vibrating piece 130 includes excitation electrodes 131 on the principal surfaces at the +Y′-axis side and the −Y′-axis side. From the respective excitation electrodes 131, extraction electrodes 132 are extracted in the −X-axis direction. The extraction electrode 132 connected to the excitation electrode 131 formed on the surface at the −Y′-axis side is extracted to the end at the −X-axis side and the −Z′-axis side on the surface at the −Y′-axis side. Further, the extraction electrode 132, which is connected to the excitation electrode 131 formed at the +Y′-axis side, extends from the excitation electrode 131 to the −X-axis side and the +Z′-axis side. The extraction electrode 132 is extracted to the end at the −X-axis side and the +Z′-axis side on the surface at the −Y′-axis side via the side surface at the +Z′-axis side. The excitation electrode 131 and the extraction electrode 132, which are formed at the piezoelectric vibrating piece 130, are formed, for example, as follows. A chromium (Cr) layer is formed at the piezoelectric vibrating piece 130, and a gold (Au) layer is formed over the top of the chromium layer.

The lid substrate 110 includes a depressed portion 111 on the surface at the −Y′-axis side. Additionally, a bonding surface 112 is formed at the periphery of the depressed portion 111. The lid substrate 110 bonds to the base substrate 120 at the bonding surface 112.

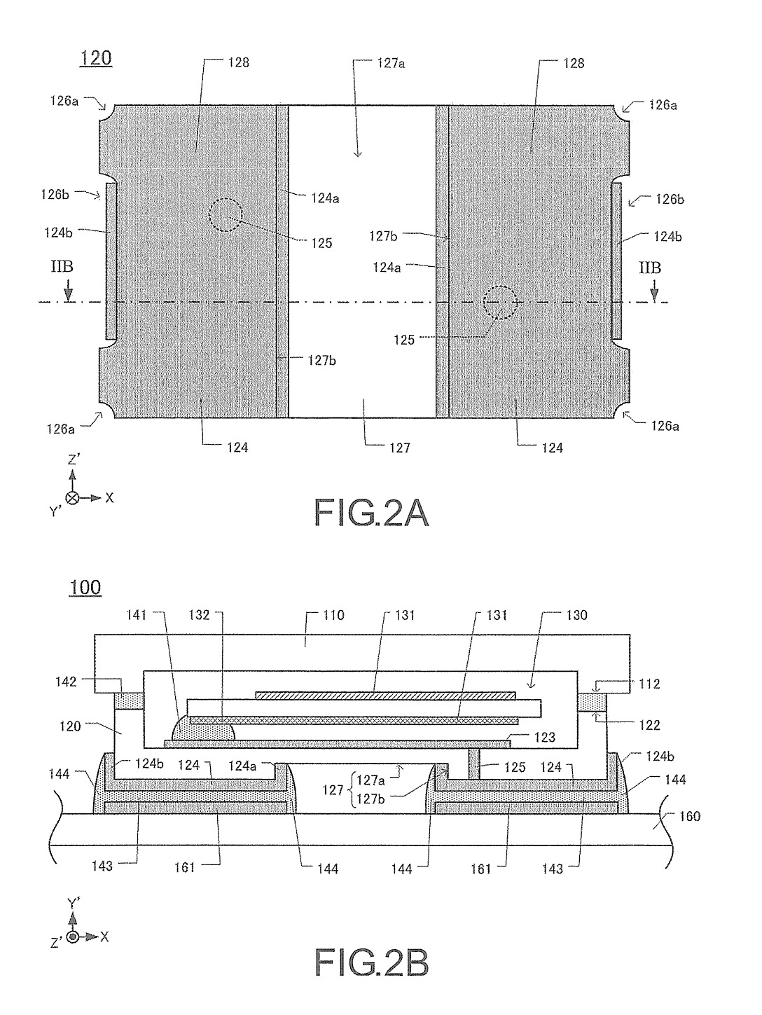

The base substrate 120 includes a depressed portion 121 depressed in the −Y′-axis direction on the surface at the +Y′-axis side. A bonding surface 122 is formed at the periphery of the depressed portion 121 on the surface at the +Y′-axis side. In the depressed portion 121, a pair of connecting electrodes 123 is formed and the pair of connecting electrodes 123 is electrically connected to the extraction electrodes 132 of the piezoelectric vibrating piece 130. The base substrate 120 includes a mounting surface 128 and a groove 127 on the surface at the −Y′-axis side. The mounting surface 128 is for surface mounting the piezoelectric device 100 to a printed circuit board or similar member. The groove 127 is depressed from the mounting surface 128 in the +Y′-axis direction. The mounting terminal 124 is formed on the mounting surface 128. The mounting terminal 124 electrically connects to a printed circuit electrode formed at the printed circuit board via a solder or similar member. Additionally, the pair of connecting electrodes 123 and the pair of mounting terminals 124 are electrically connected each other via a through electrode 125 (see FIG. 2A) that passes through the base substrate 120. The base substrate 120 is formed by an insulating material such as a piezoelectric material, for example, a ceramics, a glass, or a crystal.

FIG. 2A is a plan view of the surface at the −Y′-axis side of the base substrate 120. The base substrate 120 is in a rectangular shape that includes a long side extending in the X-axis direction and a short side extending in the Z′-axis direction. And, the base substrate 120 includes castellations 126a and castellations 126b. The castellations 126a are depressed in the center direction of the base substrate 120 and formed at four corners of the side surfaces of the base substrate 120. The castellations 126b are formed at the center of the short sides of the base substrate 120. The base substrate 120 includes one groove 127 at the center of the surface at the −Y′-axis side extending in the Z′-axis direction. The groove 127 includes a bottom surface 127a and side surfaces 127b. The bottom surface 127a is in the X-Z′ plane depressed in the +Y′-axis direction from the mounting surface 128. The side surface 127b is vertical to the X-axis direction and extends from the bottom surface 127a to the mounting surface 128. The pair of mounting terminals 124 are formed on the surface at the −Y′-axis side of the base substrate 120. Each mounting terminal 124 is formed at the +X-axis side and at the −X-axis side of the base substrate 120 and on the mounting surface 128. The mounting terminals 124 also extend from the mounting surface 128 to the side surface 127b and the castellation 126b. These respective mounting terminals 124, which are formed at the side surface 127b and the castellation 126b, are assumed as the side surface electrode 124a and the castellation electrode 124b.

FIG. 2B is a cross-sectional view of a printed circuit board 160 and the piezoelectric device 100. FIG. 2B includes a cross section taken along the line IIB-IIB of FIG. 1 and a cross section taken along the line IIB-IIB of FIG. 2A. The piezoelectric vibrating piece 130 is secured to the base substrate 120 with conductive adhesive 141. The extraction electrode 132 of the piezoelectric vibrating piece 130 is electrically connected to the connecting electrode 123 formed at the base substrate 120 via the conductive adhesive 141. The lid substrate 110 and the base substrate 120 are bonded together via a sealing material 142 formed between the bonding surface 112 and the bonding surface 122. On the other hand, a printed circuit board electrode 161 is formed on the printed circuit board 160. The piezoelectric device 100 is mounted to the printed circuit board 160 by bonding the mounting terminal 124 and the printed circuit board electrode 161 together with a solder 143. The mounting terminal 124, which is formed at the base substrate 120, includes a side surface electrode 124a and a castellation electrode 124b. The solders 143 are also formed on the surfaces of the side surface electrode 124a and the castellation electrode 124b. By forming the solder 143 at the side surface electrode 124a and the castellation electrode 124b, a fillet 144, which is the solder 143 overflown between the printed circuit board electrode 161 and the mounting terminal 124, is formed.

In the piezoelectric device 100, the solder 143 is also formed at the side surface electrode 124a and the castellation electrode 124b, and the fillet 144 is formed. These broaden the area where the solder 143 and the mounting terminal 124 are to be contacted. In view of this, a bonding strength between the mounting terminal 124 and the printed circuit board electrode 161 are increased, and this prevents the piezoelectric device 100 from being detached from the printed circuit board 160. The solder 143 is highly wettable to the mounting terminal 124. The solder 143, which attempts to overflow from between the printed circuit board electrode 161 and the mounting terminal 124, is preferentially formed on the surfaces of the side surface electrode 124a and the castellation electrode 124b. This prevents the solder 143 from disorderly overflowing from between the printed circuit board electrode 161 and the mounting terminal 124. This also prevents the solder 143, which overflows from between the mounting terminals 124, from connecting to each other and short circuiting. Additionally, formation of the solder 143 at the castellation electrode 124b enables a visual check of the bonding state of the piezoelectric device 100 to the printed circuit board 160 from outside of the piezoelectric device 100.

### Constitution of the Base Substrate 220

In the base substrate 120, two grooves may be formed between the pair of mounting terminals 124. A description will be given of the base substrate 220 where two grooves 227 are disposed instead of the groove 127 between the pair of mounting terminals 124 as a modification of the base substrate 120.

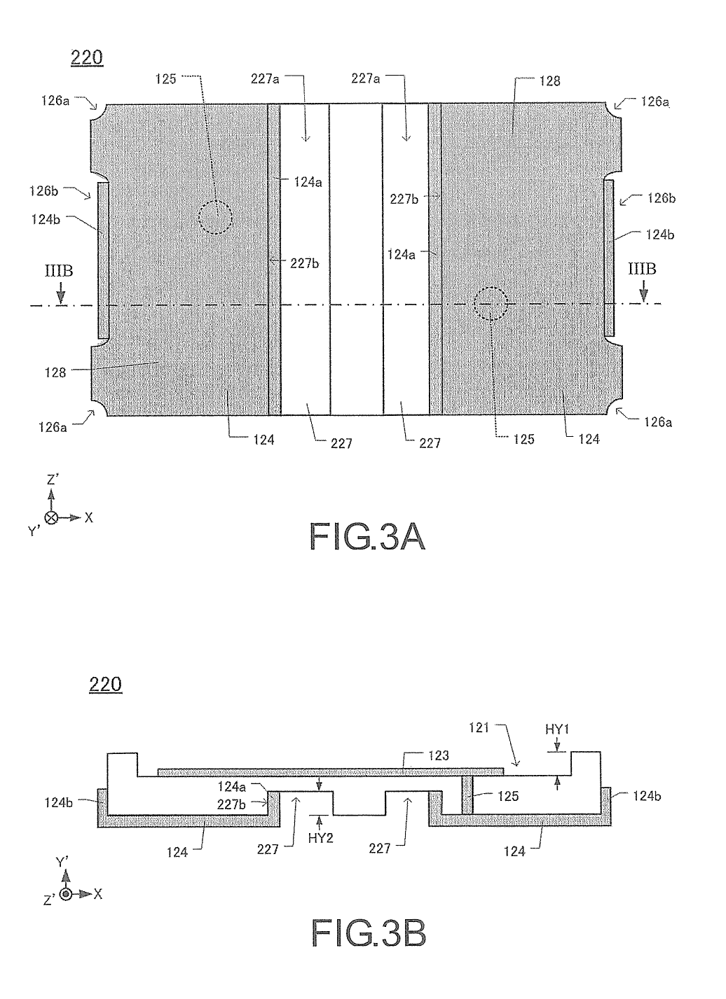

FIG. 3A is a plan view of the surface at the −Y′-axis side of the base substrate 220. In the base substrate 220, the two grooves 227 are formed between the pair of mounting terminals 124. Each groove 227 extends in the Z′-axis direction. The groove 227 includes a bottom surface 227a and a side surface 227b. The bottom surface 227a is depressed in the +Y′-axis direction from the mounting surface 128 and is in the X-Z′ plane. The side surface 227b is vertical to the X-axis direction and extends from the bottom surface 227a to the mounting surface 128. The side surface electrode 124a, which is a part of the mounting terminal 124, is formed on one side of the side surface 227b of each groove 227. Since the grooves 227 do not contact each other, even if the solder 143 overflows to the grooves 227 from the mounting terminals 124, electrical contact by the solders 143 overflowing from the respective mounting terminals 124 is avoided.

FIG. 3B is a cross-sectional view taken along the line IIIB-IIIB of FIG. 3A. In the base substrate 220, assume that the depth of the depressed portion 121 is HY1 and the depth of the groove 227 is HY2. The depth HY1 and the depth HY2 are formed equally. When the base substrate 220 is formed by a glass, a crystal, or similar material, the depressed portion 121 and the groove 227 can be formed by using etching in fabrication of the base substrate 220. In the base substrate 220, the depressed portion 121 and the groove 227 can be formed simultaneously by etching both of them at the same time, and making the depths of the depressed portion 121 and the groove 227 the same. Thus, in the case where the depressed portion 121 and the groove 227 are simultaneously etched, the number of etching, that is, the number of fabrication processes of the base substrate 220 can be reduced, which is preferred. This formation where the depths of the depressed portion 121 and the groove are formed in the same may be applicable to another embodiment.

### Second Embodiment

A plurality of three or more mounting terminals may be formed on the base substrate. A description will be given of the base substrate where four mounting terminals are formed as a second embodiment. The embodiment will now be described wherein like reference numerals designate corresponding or identical elements throughout the embodiments.

### Constitution of a Base Substrate 320

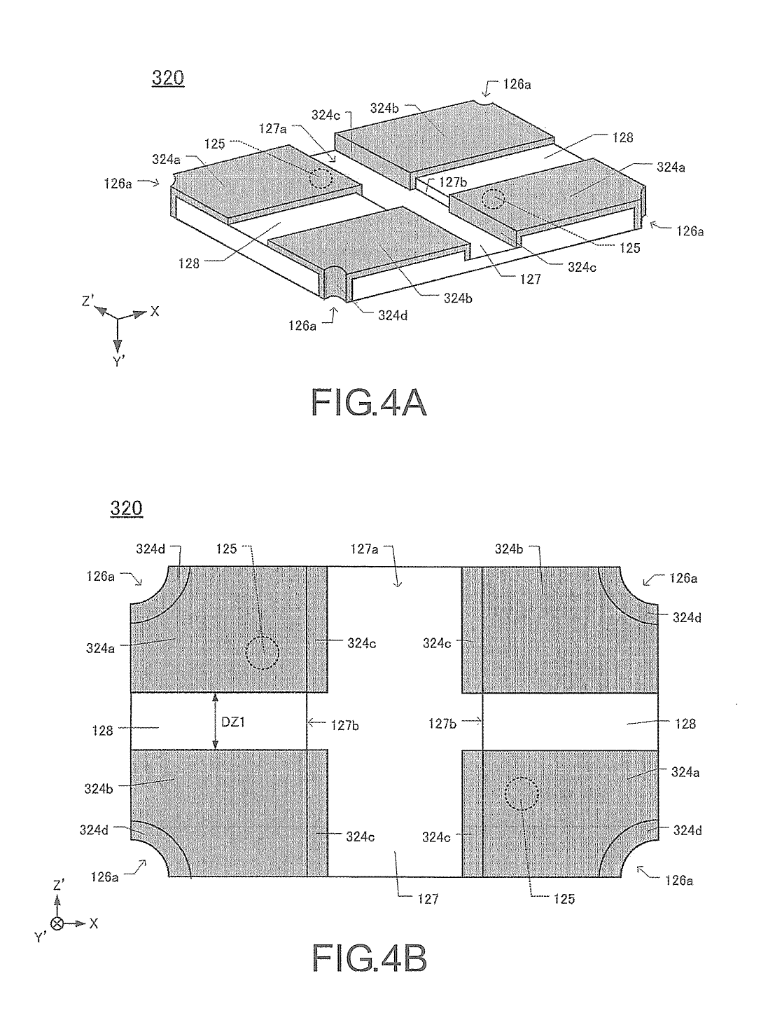

FIG. 4A is a perspective view of the surface at the −Y′-axis side of the base substrate 320. The base substrate 320 includes the castellations 126a at four corners of the side surfaces. Similar to the base substrate 120 illustrated in FIG. 2A, one groove 127 is formed on the surface at the −Y′-axis side of the base substrate 320. The base substrate 320 includes four mounting terminals 324 on the surface at the −Y′-axis side. The mounting terminals 324 are constituted of a pair of hot terminals 324a and a pair of grounding terminals 324b. The hot terminals 324a are formed on the surface at the −Y′-axis side and at the +X-axis side and the −Z′-axis side and at the −X-axis side and the +Z′-axis side of the base substrate 320. The hot terminal 324a is formed as a terminal to be electrically connected to the excitation electrode 131 of the piezoelectric vibrating piece 130 via a through electrode 125. The grounding terminals 324b are formed on the surface at the −Y′-axis side and at the +X-axis side and the +Z′-axis side and at the −X-axis side and the −Z′-axis side of the base substrate 320 as terminals for grounding the piezoelectric device. The hot terminal 324a and the grounding terminal 324b include a side surface electrode 324c, which is formed at the side surface 127b of the groove 127, and a castellation electrode 324d formed at the castellation 126a.

FIG. 4B is a plan view of the surface at the −Y′-axis side of the base substrate 320. In a piezoelectric device including the base substrate 320, the solder 143, which is formed at the mounting terminal 324, is formed including the fillet 144 as illustrated in FIG. 2B. Therefore, similarly to the base substrate 120, a bonding strength between the mounting terminal 324 and the printed circuit board electrode 161 of the printed circuit board 160 can be increased. In the base substrate 320, the side surface electrode 324c and the castellation electrode 324d are formed. This enables the solder 143 to be selectively guided in the orientation of the side surface electrode 324c and the castellation electrode 324d. Accordingly, in the base substrate 320, even if a distance DZ1, which is a distance between the hot terminal 324a and the grounding terminal 324b aligned in the Z′-axis direction, is formed narrowly, the solder 143 is selectively directed in the orientation of the side surface electrode 324c and the castellation electrode 324d. This prevents the solder 143 from forming an electrical connection at the hot terminal 324a and the grounding terminal 324b aligned in the Z′-axis direction.

### Constitution of a Base Substrate 420

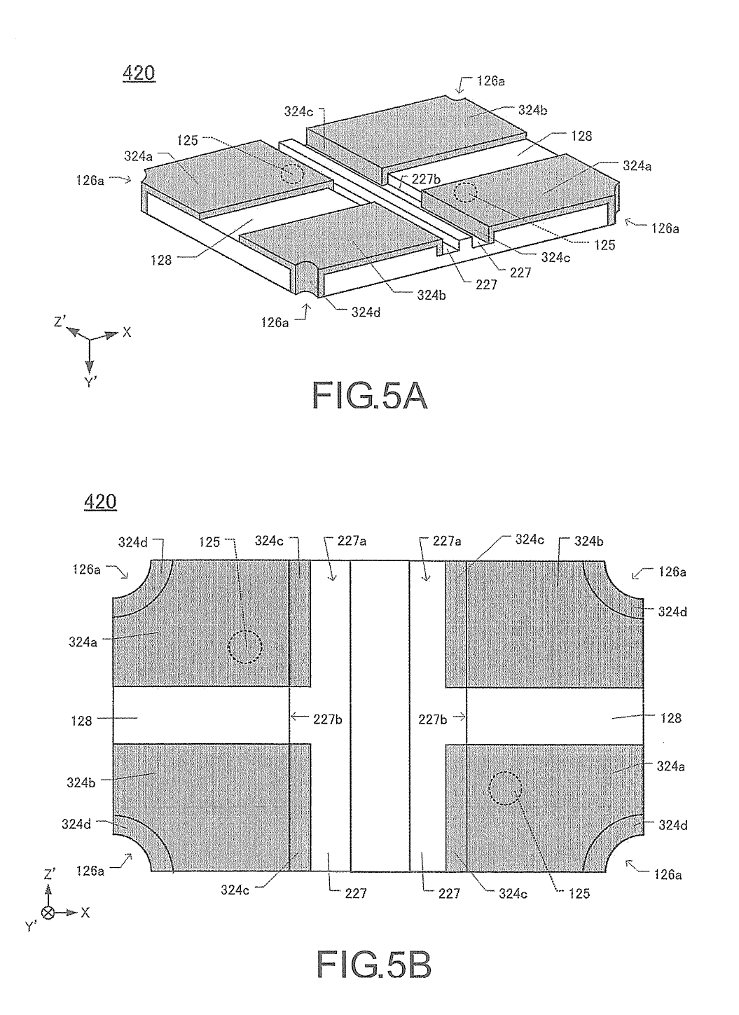

FIG. 5A is a perspective view of the surface at the −Y′-axis side of the base substrate 420. Instead of one groove 127 in the base substrate 320, the two grooves 227 illustrated in FIG. 3A and FIG. 3B are formed in the base substrate 420. Other constitutions of the base substrate 420 are similar to those of the base substrate 320.

FIG. 5B is a plan view of the surface at the −Y′-axis side of the base substrate 420. In the base substrate 420, the two grooves 227 do not connect to each other. Even if the solder 143 formed at each mounting terminal 324 flows into the grooves 227, the solder 143 formed at the mounting terminals 324 facing each other in the X-axis direction are not in electrical contact.

### Constitution of a Base Substrate 520

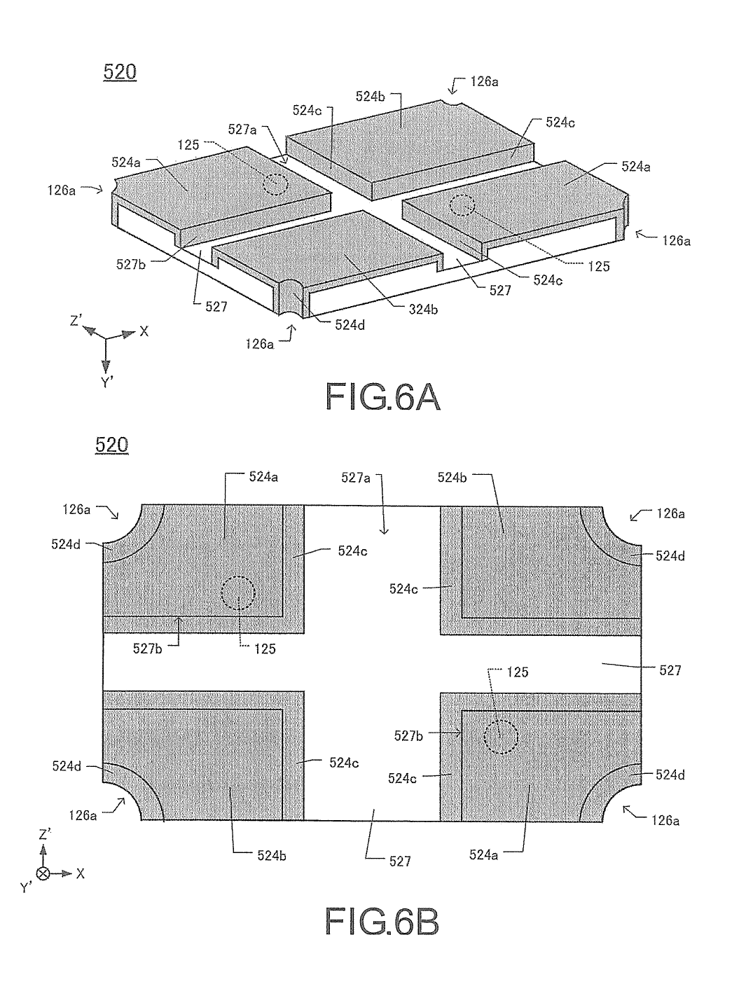

FIG. 6A is a perspective view of the surface at the −Y′-axis side of the base substrate 520. The base substrate 520 includes the castellations 126a at four corners of the side surfaces. The base substrate 520 includes a cross-shaped groove 527 on the surface at the −Y′-axis side. The groove 527 includes a bottom surface 527a and a side surface 527b. The groove extending in the X-axis direction and the groove extending in the Z′-axis direction intersect at the center of the surface at the −Y′-axis side of the base substrate 520. The base substrate 520 includes four mounting terminals 524 on the surface at the −Y′-axis side. The mounting terminals 524 include a pair of hot terminals 524a and a pair of grounding terminals 524b. The hot terminals 524a are formed on the surface at the −Y′-axis side and at the +X-axis side and the −Z′-axis side and at the −X-axis side and the +Z′-axis side of the base substrate 520. The grounding terminals 524b are formed on the surface at the −Y′-axis side and at the +X-axis side and the +Z′-axis side and at the −X-axis side and the −Z′-axis side of the base substrate 520. The hot terminal 524a and the grounding terminal 524b include a side surface electrode 524c, which is formed at the side surface 527b of the groove 527, and a castellation electrode 524d formed at the castellation 126a.

FIG. 6B is a plan view of the surface at the −Y′-axis side of the base substrate 520. Each mounting terminal 524 formed at the base substrate 520 includes the side surface electrode 524c formed at the X-axis side, the side surface electrode 524c formed at the Z′-axis side, and the castellation electrode 524d formed at the castellation 126a side. Thus, each mounting terminal 524 includes electrodes on side surfaces in three orientations. This broadens the surface area of the mounting terminal 524. Accordingly, this increases a bonding strength between the mounting terminals 524 and the printed circuit board 160.

### Constitution of a Base Substrate 620

FIG, 7A is a perspective view of the surface at the −Y′-axis side of the base substrate 620. The base substrate 620 includes the groove 527 on the surface at the −Y′-axis side and the castellations 126a at four corners of the side surfaces. The base substrate 620 includes the mounting terminal 324 illustrated in FIG. 4A and FIG. 4B. In each mounting terminal 324, the side surface electrode 324c is formed at the side surface 527b that is in contact in the X-axis direction of the groove 527. A side surface electrode is not formed at the side surface 527b that is in contact in the Z′-axis direction of the groove 527.

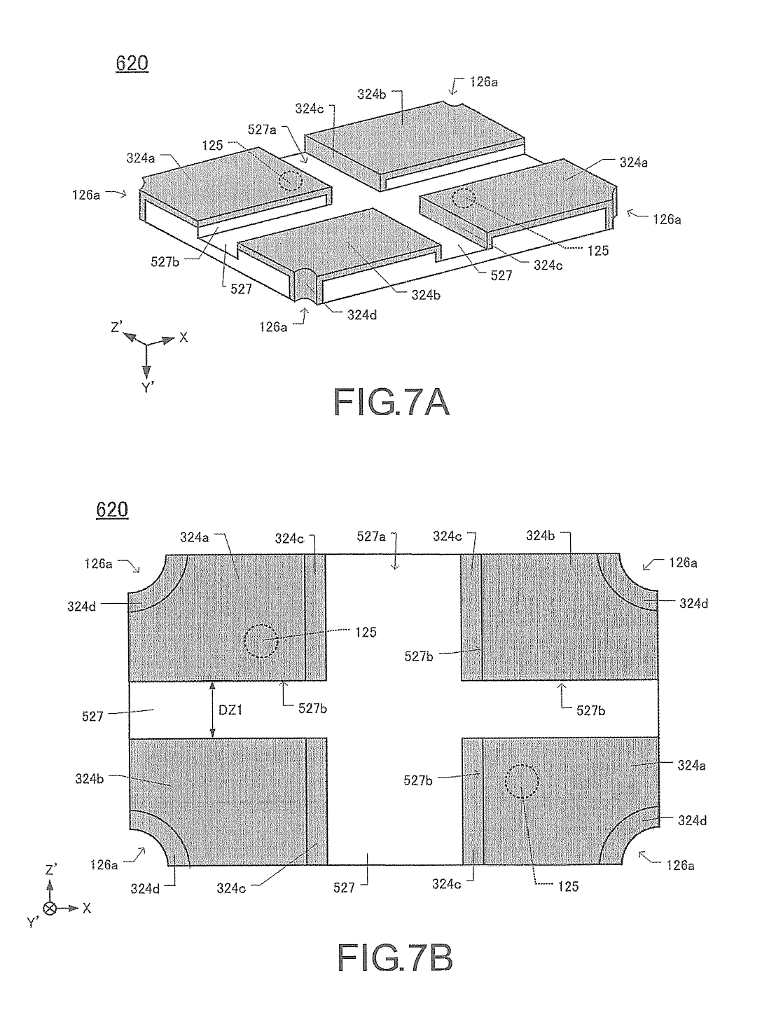

FIG. 7B is a plan view of the surface at the −Y′-axis side of the base substrate 620. In the groove 527 formed at the base substrate 620, the width of the groove extending in the Z′-axis direction is formed larger than the width of the groove extending in the X-axis direction. Therefore, in the base substrate 620, similarly to the base substrate 320 illustrated in FIG. 4B, even if the distance DZ1, which is a distance between the hot terminal 324a and the grounding terminal 324b aligned in the Z′-axis direction, is formed narrowly, the solder 143 flows in the orientation of the groove extending in the Z′-axis direction by formation of the side surface electrode 324c. This prevents the solder 143 from forming an electrical connection at the hot terminal 324a and the grounding terminal 324b aligned in the Z′-axis direction.

### Constitution of a Base Substrate 720

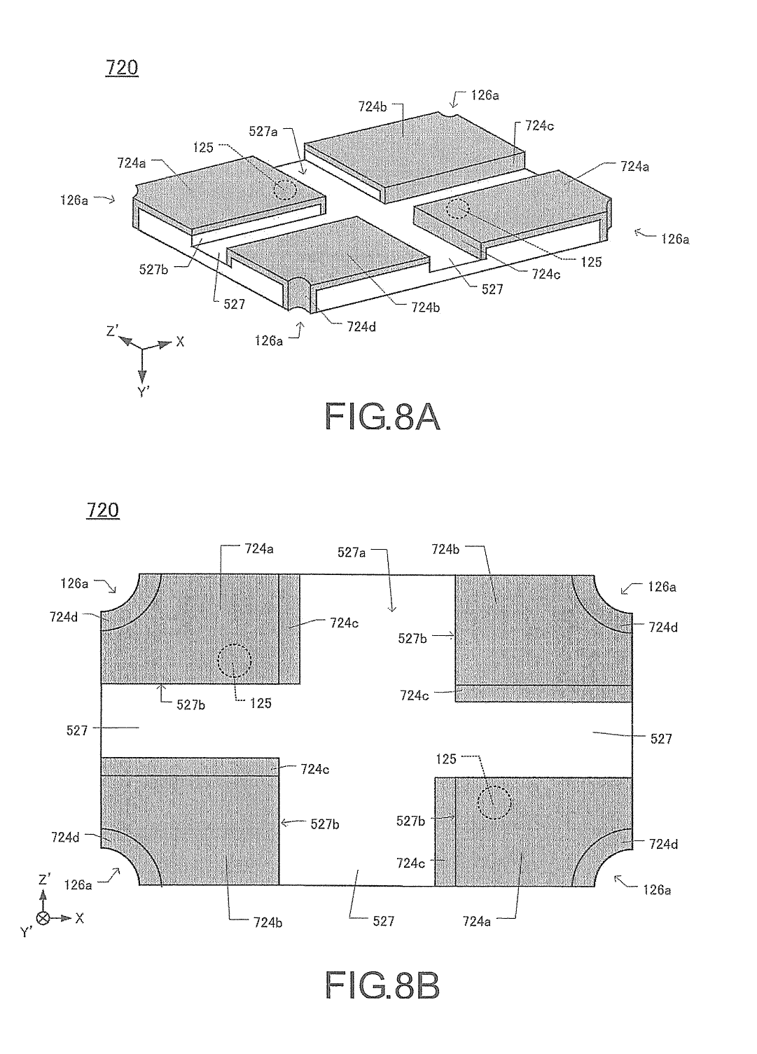

FIG. 8A is a perspective view of the surface at the −Y′-axis side of a base substrate 720. The base substrate 720 includes the groove 527, the castellation 126a, and a mounting terminal 724 on the surface at the −Y′-axis side. The mounting terminals 724 include a pair of hot terminals 724a and a pair of grounding terminals 724b. The hot terminals 724a are formed on the surface at the −Y′-axis side and at the +X-axis side and the −Z′-axis side and at the −X-axis side and the +Z′-axis side of the base substrate 720. The grounding terminals 724b are formed on the surface at the −Y′-axis side and at the +X.-axis side and the +Z′-axis side and at the −X-axis side and the −Z′-axis side of the base substrate 720. The hot terminal 724a and the grounding terminal 724b include a side surface electrode 724c, which is formed at a part of the side surface 527b of the groove 527, and a castellation electrode 724d formed at the castellation 126a.

FIG. 8B is a plan view of the surface at the −Y′-axis side of the base substrate 720. The hot terminal 724a formed in the +X-axis direction and at the −Z′-axis side includes a side surface electrode 724c on the side surface 527b at the −X-axis side. The grounding terminal 724b formed in the −X-axis direction and at the −Z-axis side includes a side surface electrode 724c on the side surface 527b at the +Z′-axis side. The hot terminal 724a formed in the −X-axis direction and at the +Z′-axis side includes a side surface electrode 724c on the side surface 527b at the +X-axis side. The grounding terminal 724b formed in the +X-axis direction and at the +Z′-axis side includes a side surface electrode 724c on the side surface 527b at the −Z′-axis side. That is, the side surface electrode 724c is formed at a clockwise location of each mounting terminal 724. Accordingly, the solder 143 between the adjacent mounting terminals 724 do not overflow in the direction facing each other. Thus, an electrical connection between the solder 143 can be avoided. FIG. 8B illustrates a case where the side surface electrode 724c of each mounting terminal 724 is formed at a clockwise location. The side surface electrode 724c may be formed at a counterclockwise location.

Representative embodiments are described in detail above; however, as will be evident to those skilled in the relevant art, this disclosure may be changed or modified in various ways within its technical scope.

For example, in the base substrate according to the above-described embodiments, the mounting terminal electrically connects to the excitation electrode via the through electrode 125. In addition to these embodiments, a castellation electrode formed at a castellation of the base substrate may be employed instead of the through electrode 125. The castellation electrode may be electrically connected to the connecting electrode 123 so as to electrically connect the mounting terminal and the excitation electrode. Additionally, the piezoelectric device may be a crystal controlled oscillator that includes an integrated circuit.

Additionally, the above-described embodiments disclose a case where the piezoelectric vibrating piece 130 is an AT-cut quartz-crystal vibrating piece. A BT-cut quartz-crystal vibrating piece or similar member that similarly vibrates in the thickness-shear mode is similarly applicable. This disclosure is also applicable to a tuning-fork type quartz-crystal vibrating piece. Further, the piezoelectric vibrating piece is basically applicable to a piezoelectric material that includes not only a quartz-crystal material but also lithium tantalite, lithium niobate, and piezoelectric ceramics.

In the first aspect of the disclosure, the piezoelectric device according to a second aspect is configured as follows. The base substrate is in a rectangular shape having a short side and a long side. The groove extends at an approximate center of the long side in the short side direction. The groove is formed only between the pair of mounting terminals. The mounting terminals are formed on the mounting surface and the side surfaces at the long side direction side.

In the first aspect of the disclosure, the piezoelectric device according to a third aspect is configured as follows. The base substrate is in a rectangular shape having a short side and a long side. The groove between the two pairs of mounting terminals is formed in a cross shape when viewed from a normal direction of the mounting surface. The mounting terminals are formed on the mounting surface and the side surfaces at the long side direction side. The mounting terminals are not formed on the side surfaces at the short side direction side.

In the first aspect of the disclosure, the piezoelectric device according to a fourth aspect is configured as follows. The base substrate is in a rectangular shape having a short side and a long side. The groove between the two pairs of mounting terminals is formed in a cross shape when viewed from a normal direction of the mounting surface. The respective mounting terminals are formed clockwise or counterclockwise when viewed from the normal direction of the mounting surface. The mounting terminals are formed on the side surface at the long side direction side, the side surface at the short side direction side, the side surface at the long side direction side, and the side surface at the short side direction side.

In the first aspect to the fourth aspect of the disclosure, the piezoelectric device according to a ⁻fifth aspect is configured as follows. The groove is formed double between the pair of mounting terminals.

In the first aspect to the fifth aspect of the disclosure, the piezoelectric device according to a sixth aspect is configured as follows. The base substrate is made of glass or piezoelectric material. The base substrate includes a depressed portion at a center of a bonding surface on an opposite side of the mounting surface. The depressed portion and the groove are formed simultaneously by etching.

In the sixth aspect of the disclosure, the piezoelectric device according to a seventh aspect is configured as follows. The depressed portion and the groove are formed at the same depth.

In the sixth aspect or the seventh aspect of the disclosure, the piezoelectric device according to an eighth aspect is configured as follows. The base substrate includes a castellation. The castellation is depressed at a center side from the bonding surface to the mounting surface. The mounting terminal is also formed on the castellation.

This disclosure provides a piezoelectric device that prevents a short circuit between mounting terminals.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A surface mount piezoelectric device with a piezoelectric vibrating piece to be mounted on a surface of a printed circuit board, the piezoelectric device comprising:
a base substrate formed of an insulating material, the base substrate including a mounting surface to be mounted on the printed circuit board;
a groove formed on at least a part of a periphery of the mounting terminal, the groove having a bottom surface and a side surface, the side surface extending from the bottom surface to the mounting surface; and
at least a pair of mounting terminals formed on the mounting surface and the side surface.

2. The surface mount piezoelectric device according to claim 1, wherein
the base substrate is in a rectangular shape having a short side and a long side,
the groove extends at an approximate center of the long side in the short side direction, the groove being formed only between the pair of mounting terminals, and
the mounting terminals are formed on the mounting surface and the side surfaces at the long side direction side.

3. The surface mount piezoelectric device according to claim 1, wherein
the base substrate is in a rectangular shape having a short side and a long side,
the groove between the two pairs of mounting terminals is formed in a cross shape when viewed from a normal direction of the mounting surface, and
the mounting terminals are formed on the mounting surface and the side surfaces at the long side direction side, the mounting terminals being not formed on the side surfaces at the short side direction side.

4. The surface mount piezoelectric device according to claim 1, wherein
the base substrate is in a rectangular shape having a short side and a long side,
the groove between the two pairs of mounting terminals is formed in a cross shape when viewed from a normal direction of the mounting surface, and
the respective mounting terminals are formed clockwise or counterclockwise when viewed from the normal direction of the mounting surface,
the mounting terminals being formed on the side surface at the long side direction side, the side surface at the short side direction side, the side surface at the long side direction side, and the side surface at the short side direction side.

5. The surface mount piezoelectric device according to claim 1, wherein
the groove is formed double between the pair of mounting terminals.

6. The surface mount piezoelectric device according to claim 1, wherein
the base substrate is made of glass or piezoelectric material,
the base substrate includes a depressed portion at a center of a bonding surface on an opposite side of the mounting surface, and
the depressed portion and the groove are formed simultaneously by etching.

7. The piezoelectric vibrating piece according to claim 6, wherein
the depressed portion and the groove are formed at the same depth.

8. The surface mount piezoelectric device according to claim 6, wherein
the base substrate includes a castellation, the castellation being depressed at a center side from the bonding surface to the mounting surface, and
the mounting terminal is also formed on the castellation.
